(19) United States
(12) Patent Application Publication
(10) Pub. No.: US 2012/0119814 A1
(43) Pub. Date: May 17, 2012

(54) POWER OFF CIRCUIT AND ELECTRONIC DEVICE

(75) Inventor: XING-HUA TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/171,457

(22) Filed: Jun. 29, 2011

(30) Foreign Application Priority Data
Nov. 12, 2010 (CN) 201010542476.X

(51) Int. Cl. H03K 17/28

(52) U.S. Cl. 327/398

(57) ABSTRACT

A power off circuit includes a switching unit, a detecting unit, a power management unit, a delay unit, and a control unit. The switching unit is connected to a power source. The detecting unit detects whether the switching unit is turned off and generates a detecting signal when detecting that the switching unit is turned off. The power management unit receives a supply voltage from the power source and provides an operating voltage to at least one functional module. The control unit signals the at least one functional module to be ready for being powered off according to the detecting signal. The delay unit generates a control signal after a predetermined time period from a time point when the switching unit is turned off, the power management unit stops providing the operating voltage to the at least one functional module according to the control signal.

### BACKGROUND

1. Technical Field

The disclosed embodiments relate to power off circuits, and more particularly to a power off circuit and an electronic device using the power off circuit.

2. Description of Related Art

Power off circuits are widely used in electronic devices, such as digital versatile disc (DVD) player, notebook computers, etc. Generally, an electronic device includes a power source, a power off circuit, and functional modules. The power off circuit includes a control unit and a power management unit. The power management unit receives a supply voltage from the power source and provides a working voltage to the functional modules. When the electronic device receives a power off command input by a user, the control unit signals the functional modules to be ready for being powered off, for example, the functional modules need to store data in time before the electronic device is powered off.

When the functional modules have stored data completely, the control unit executes software programs to disable the power management unit. However, when a glitch occurs in the software programs, the control unit may malfunction, thus the power management unit cannot be disabled, and the electronic device will not be powered off.

What is needed, therefore, is a power off circuit and an electronic device to overcome the above described limitations.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout two views.

FIG. 1 is a block diagram showing an electronic device in accordance with one embodiment.

FIG. 2 is a circuit diagram of the electronic device of FIG. 1.

### DETAILED DESCRIPTION

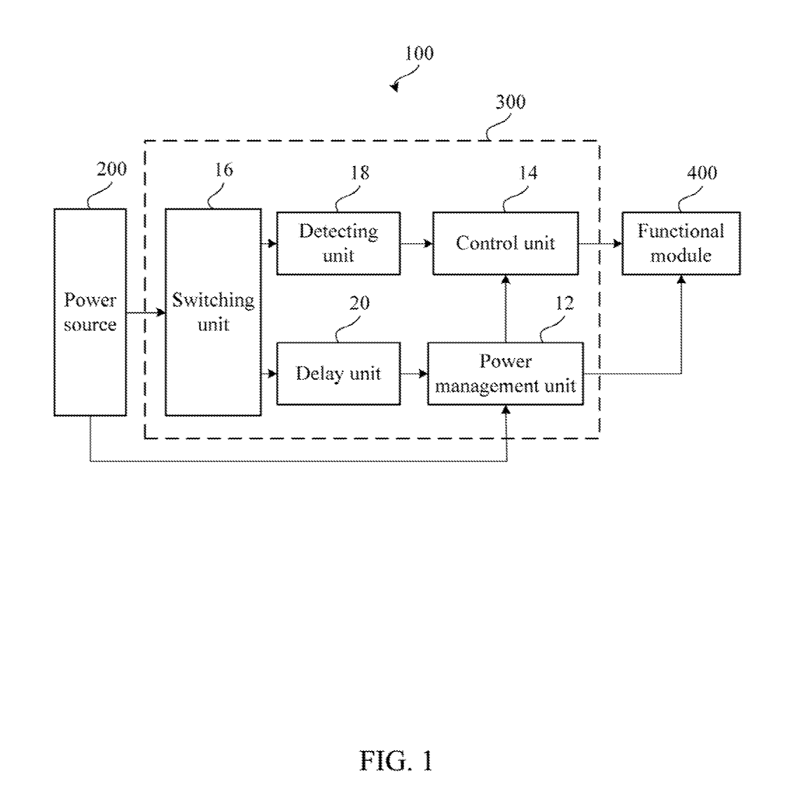

Referring to FIG. 1, an electronic device 100 includes a power source 200, a power off circuit 300, and at least one functional module 400. The electronic device 100 can be a digital versatile disc (DVD) player, a notebook computer, etc. The power source 200 is used for providing a supply voltage.

The power off circuit 300 includes a power management unit 12, a control unit 14, a switching unit 16, a detecting unit 18, and a delay unit 20. The power management unit 12 is used for receiving the supply voltage from the power source 200 and providing an operating voltage to the control unit 14 and the at least one functional module 400, therefore the control unit 14 is enabled and the at least one functional module 400 performs a predetermined function.

The detecting unit 18 is connected to the power source 200 through the switching unit 16, and the delay unit 20 is connected to the power source 200 through the switching unit 16. When the switching unit 16 is turned on, the power source 200 provides the supply voltage to the detecting unit 18 and the delay unit 20. When the switching unit 16 is turned off, the power source 200 stops providing the supply voltage to the detecting unit 18 and the delay unit 20. The detecting unit 18 is used for detecting whether the switching unit 16 is turned off and generating a detecting signal when detecting that the switching unit 16 is turned off. The control unit 14 signals the at least one functional module 400 to be ready for being powered off according to the detecting signal, for example, the at least one functional module 400 needs to store data in time before the electronic device 100 is powered off.

The delay unit 20 is connected to the power management unit 12 and the switching unit 16. The delay unit 20 generates a control signal after a predetermined time period from a time point when the switching unit 16 is turned off, the power management unit 12 stops providing the operating voltage to the control unit 14 and the at least one functional module 400 according to the control signal. Therefore, the control unit 14 and the at least one functional module 400 are disabled, and the electronic device 100 is powered off. During the predetermined time period, the at least one functional module 400 stores data in time, thus the data loss is effectively prevented.

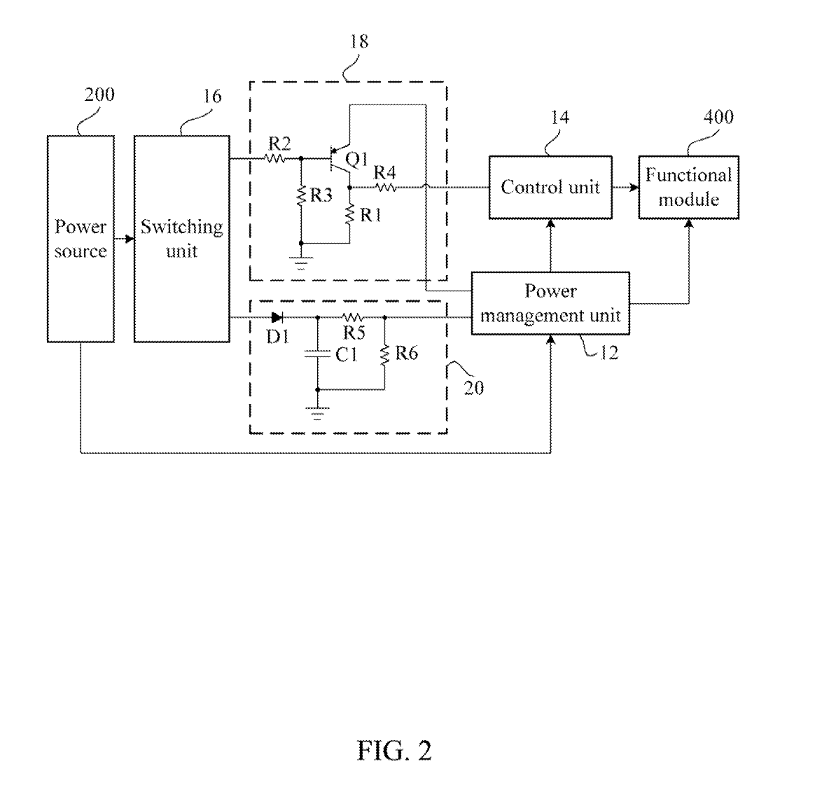

Referring to FIG. 2, the detecting unit 18 includes a transistor Q1, a first resistor R1, a second resistor R2, a third resistor R3, and a fourth resistor R4. An emitter of the transistor Q1 is connected to the power management unit 12, a collector of the transistor Q1 is grounded through the first resistor R1, a base of the transistor Q1 is connected to the switching unit 16 through the second resistor R2. One end of the third resistor R3 is connected between the second resistor R2 and the base of the transistor Q1, the other end of the third resistor R3 is grounded. One end of the fourth resistor R4 is connected to the collector of the transistor Q1, the other end of the fourth resistor R4 is connected to the control unit 14. In this embodiment, the transistor Q1 is a PNP type transistor.

The delay unit 20 includes a capacitor C1, a fifth resistor R5, a sixth resistor R6, and a diode D1. One end of the fifth resistor R5 is connected to the power management unit 12, an anode of the diode D1 is connected to the switching unit 16, a cathode of the diode D1 is connected to the other end of the fifth resistor R5. One end of the sixth resistor R6 is connected between the fifth resistor R5 and the power management unit 12, the other end of the sixth resistor R6 is grounded. One end of the capacitor C1 is connected between the cathode of the diode D1 and the fifth resistor R5, the other end of the capacitor C1 is grounded. In this embodiment, the capacitance of the capacitor C1 is adjustable.

The principle of the electronic device 100 is illustrated as follows:

The power management unit 12 receives the supply voltage from the power source 200 and provides the operating voltage to the emitter of the transistor Q1. When the switching unit 16 is turned on, the supply voltage from the power source 200 is transmitted to the base of the transistor Q1 through the resistor R2, thus the transistor Q1 is cut off; at the same time, the supply voltage from the power source 200 charges up the capacitor C1 through the diode D1, and capacitor C1 stores energy. When the switching unit 16 is turned off, the base of the transistor Q1 is pulled low, thus the transistor Q1 conducts; then the operating voltage from the power management unit 12 is transmitted to the control unit 14 through the emitter and the collector of the transistor Q1 and the resistor R4; thus the detecting unit 18 generate the high voltage level detecting signal to the control unit 14. The control unit 14 signals the at least one functional module 400 to store data in time before being powered off according to the detecting signal.

At the same time, when the switching unit 16 is turned off, the capacitor C1 discharges through the fifth resistor R5 and the sixth resistor R6. After the predetermined time period T, T is calculated by the following formula: T=C1*(R5+R6), from the time point when the switching unit 16 is turned off, the capacitor C1 has been discharged completely, thus the delay unit 20 generates the low voltage level control signal to the power management unit 12. The power management unit 12 stops providing the operating voltage to the control unit 14, the delay unit 18, and the at least one functional module 400 according to the control signal, so that the electronic device 100 is powered off with no glitches or less likely chance of glitches.

In this embodiment, the delay unit 20 controls the power management unit 12 to stop providing the operating voltage to the control unit 14 and the at least one functional module 400, and the delay unit 20 includes the capacitor C1, the resistors R5, R6, and the diode D1. Because the delay unit 20 generates the low voltage level control signal to disable the power management unit 12, but does not execute software programs to disable the power management unit 12; the error of the software programs is effectively prevented, and the electronic device 100 is powered off.

Alternative embodiments will become apparent to those skilled in the art without departing from the spirit and scope of what is claimed. Accordingly, the present invention should be deemed not to be limited to the above detailed description, but rather only by the claims that follow and equivalents thereof.

What is claimed is:

1. A power off circuit, comprising:
a switching unit connected to a power source;
a detecting unit for detecting whether the switching unit is turned off and generating a detecting signal when detecting that the switching unit is turned off;
a power management unit for receiving a supply voltage from the power source and providing an operating voltage to at least one functional module;
a delay unit connected to the switching unit and the power management unit; and
a control unit;
wherein the control unit signals the at least one functional module to be ready for being powered off according to the detecting signal, the delay unit generates a control signal after a predetermined time period from a time point when the switching unit is turned off, and the power management unit stops providing the operating voltage to the at least one functional module according to the control signal.

2. The power off circuit of claim 1, wherein the power management unit further stops providing the operating voltage to the control unit according to the control signal.

3. The power off circuit of claim 1, wherein the detecting unit comprises a transistor, a first resistor, a second resistor, and a third resistor, an emitter of the transistor is connected to the power management unit, a collector of the transistor is grounded through the first resistor, a base of the transistor is connected to the switching unit through the second resistor, the collector of the transistor is connected to the control unit, one end of the third resistor is connected between the second resistor and the base of the transistor, the other end of the third resistor is grounded.

4. The power off circuit of claim 3, wherein the detecting unit further comprises a fourth resistor, one end of the fourth resistor is connected to the collector of the transistor, the other end of the fourth resistor is connected to the control unit.

5. The power off circuit of claim 3, wherein the transistor is a PNP type transistor.

6. The power off circuit of claim 1, wherein the delay unit comprises a capacitor, a fifth resistor, and a sixth resistor, one end of the fifth resistor is connected to the switching unit, the other end of the fifth resistor is connected to the power management unit, one end of the sixth resistor is connected between the fifth resistor and the power management unit, the other end of the sixth resistor is grounded, one end of the capacitor is connected between the switching unit and the fifth resistor, the other end of the capacitor is grounded.

7. The power off circuit of claim 6, wherein the capacitance of the capacitor is adjustable.

8. The power off circuit of claim 6, wherein the delay unit further comprises a diode, an anode of the diode is connected to the switching unit, a cathode of the diode is connected to the fifth resistor.

9. The power off circuit of claim 1, wherein the at least one functional module performs a predetermined function.

10. An electronic device, comprising:
a power source;
at least one functional module;
a switching unit connected to the power source;
a detecting unit for detecting whether the switching unit is turned off and generating a detecting signal when detecting that the switching unit is turned off;
a power management unit for receiving a supply voltage from the power source and providing an operating voltage to the at least one functional module;
a delay unit connected to the switching unit and the power management unit; and
a control unit;
wherein the control unit signals the at least one functional module to be ready for being powered off according to the detecting signal, the delay unit generates a control signal after a predetermined time period from a time point when the switching unit is turned off, the power management unit stops providing the operating voltage to the at least one functional module according to the control signal.

11. The electronic device of claim 10, wherein the power management unit further stops providing the operating voltage to the control unit according to the control signal.

12. The electronic device of claim 10, wherein the detecting unit comprises a transistor, a first resistor, a second resistor, and a third resistor, an emitter of the transistor is connected to the power management unit, a collector of the transistor is grounded through the first resistor, a base of the transistor is connected to the switching unit through the second resistor, the collector of the transistor is connected to the control unit, one end of the third resistor is connected between the second resistor and the base of the transistor, the other end of the third resistor is grounded.

13. The electronic device of claim 12, wherein the detecting unit further comprises a fourth resistor, one end of the fourth resistor is connected to the collector of the transistor, the other end of the fourth resistor is connected to the control unit.

14. The electronic device of claim 12, wherein the transistor is a PNP type transistor.

15. The electronic device of claim 10, wherein the delay unit comprises a capacitor, a fifth resistor, and a sixth resistor, one end of the fifth resistor is connected to the switching unit, the other end of the fifth resistor is connected to the power management unit, one end of the sixth resistor is connected between the fifth resistor and the power management unit, the other end of the sixth resistor is grounded, one end of the capacitor is connected between the switching unit and the fifth resistor, the other end of the capacitor is grounded.

16. The electronic device of claim 15, wherein the capacitance of the capacitor is adjustable.

17. The electronic device of claim 15, wherein the delay unit further comprises a diode, an anode of the diode is connected to the switching unit, a cathode of the diode is connected to the fifth resistor.

18. An electronic device, comprising:
a power source;
at least one functional module;
a switching unit connected to the power source;
a detecting unit for detecting whether the switching unit is turned off and generating a detecting signal when detecting that the switching unit is turned off;
a power management unit for receiving a supply voltage from the power source and providing an operating voltage to the at least one functional module;
a delay unit connected to the switching unit and the power management unit; and
a control unit;
wherein the control unit signals the at least one functional module to be ready for being powered off according to the detecting signal, the delay unit generates a control signal after a predetermined time period from a time point when the switching unit is turned off, the power management unit stops providing the operating voltage to the at least one functional module and the control unit according to the control signal.
